(19) United States
(12) Patent Application Publication
(10) Pub. No.: US 2025/0224699 A1
(43) Pub. Date: Jul. 10, 2025

(54) METHOD AND SYSTEM FOR VIRTUAL SIMULATION OF HAZARD ACCESSIBILITY FOR MACHINE SAFETY CONFIGURATION

(71) Applicant: Pilz GmbH & Co. KG, Ostfildern (DE)

(72) Inventors: Bernd Neuschwander, Ostfildern (DE); Ingo Tammer, Ostfildern (DE)

(21) Appl. No.: 19/048,555

(22) Filed: Feb. 7, 2025

Related U.S. Application Data
(63) Continuation of application No. PCT/EP2023/072172, filed on Aug. 10, 2023.

(30) Foreign Application Priority Data
Aug. 10, 2022 (DE) 102022120158.9

(51) Int. Cl. G05B 9/02; G06F 30/20

(52) U.S. Cl. CPC G05B 9/02; G06F 30/20

(57) ABSTRACT

A computer-implemented method for determining a safety configuration of a safety system for a machine having a hazard location. The method includes providing a virtual model of the machine in a virtual environment. The method includes simulating an accessibility of the hazard location of the machine in the virtual environment based on a plurality of three-dimensional geometric shapes. The plurality of geometric shapes has at least two different sizes. The method includes determining the accessibility of the hazard location based on the simulation of the accessibility of the hazard location. The method includes determining the safety configuration based on the accessibility of the hazard location.

### CROSS-REFERENCE TO RELATED APPLICATIONS

This application is a continuation of International Application No. PCT/EP2023/072172 filed Aug. 10, 2023, which claims priority to German Patent Application No. DE 10 2022 120 158.9 filed Aug. 10, 2022. The entire disclosures of the above applications are incorporated by reference.

### FIELD

The present invention relates to a computer-implemented method for determining a safety configuration of a safety system for a machine. Furthermore, the present invention relates to a method for configuring a safety system for a machine. Furthermore, the present invention relates to a corresponding computer program product.

### BACKGROUND

The current focus of industrial development is on enhancing the flexibility of production processes to better adapt to customer requirements. To achieve this, industry is transitioning from static production lines to reconfigurable, modular production units that can be adapted to meet specific requirements.

Reconfigurable production lines require that the machines and systems involved are equally adaptable and can be modified as needed. However, this flexibility presents new challenges for safety engineering. Each time a machine is modified, it is necessary to reassess whether the risks associated with the machine have changed and if this necessitates a realignment of the safety equipment. In Europe, for instance, this requirement is outlined in the Machinery Directive (CE), which mandates regular risk assessments throughout the entire service life of a machine.

However, to fully leverage the benefits of flexible and adaptable machine arrangements, there is a temptation to either automate the risk assessment process or have a safety engineer assist the computer with the assessment. The automatic or assisted risk assessment is based on virtual models of the machine and the safety technology employed. The models can be used to simulate changes and evaluate safety precautions before the system is modified. The automatic or assisted risk assessment, referred to below as automated risk assessment for short, can provide the safety engineer with appropriate recommendations and assist in minimizing risks in accordance with standards. A regular risk assessment can thus be carried out in a structured, fast and at least partially automated manner, especially if the automatic risk assessment can draw on real runtime data. An example of such a concept is shown in EP 3 702 855 A1.

For CE certification, a hazard analysis of machines must be carried out in accordance with the EN ISO 12100 standard. The EN ISO 12100 standard sets out the basic terminology and methodology and establishes general principles for risk assessment and risk reduction to help designers manufacture safe machinery. An important aspect of the analysis is the evaluation of hazard locations or danger spots on a machine that pose a potential danger to people. Hazard locations can be, for example, mechanical, thermal or electrical hazard locations. Mechanical hazard locations are, for example, regions of the machine that can pose a danger to people due to their surface contour, such as edges or tips. Electrical hazard locations are, for example, regions or parts of the machine that are live or energized when the machine is in operation. Thermal hazard locations are, for example, regions or parts of the machine in which heat can be generated during operation of the machine. It is understood that the skilled person may be aware of other types of hazard locations than those mentioned here.

Certification involves determining the hazard locations of a machine, checking their accessibility for people and, if necessary, safeguarding them with suitable safety measures. Until now, CE certification has been carried out manually by an inspector. In particular, the test specimen was previously analyzed manually by an inspector at his own discretion for hazard locations, the accessibility of the hazard locations was determined and, if necessary, appropriate safety measures were determined.

Various technical safety measures can be taken to safeguard hazardous regions. In particular, a safety system can be provided to safeguard certain hazard locations on the machine. The safety system can, for example, have sensors, cameras, edge protectors or barriers that can be used to safeguard the hazard locations.

The EN ISO 13857 standard specifies safety distances to prevent the human body, the upper and lower limbs, from reaching hazardous regions. To determine the accessibility of the hazardous regions of a machine, an inspector used to manually check whether the machine complied with the safety distances against reaching hazard locations in accordance with the EN ISO 13857 standard and whether any further safety measures needed to be taken.

### SUMMARY

It is an object to specify a method with which the safety of a machine can be improved. It is a further object to specify a method by means of which the safeguarding of hazard locations of a machine can be improved.

According to a first aspect of the present disclosure, this object is solved by a computer-implemented method for determining a safety configuration of a safety system for a machine, the machine having a hazard location, comprising the following steps:
providing a virtual model of the machine in a virtual environment;
simulating the accessibility of the hazard location of the machine in the virtual environment based on a plurality of three-dimensional geometric shapes, wherein the plurality of geometric shapes has at least two different sizes;
determining the accessibility of the hazard location based on the simulation of the accessibility of the hazard location; and
determining the safety configuration based on the specific accessibility of the hazard location.

According to a second aspect of the present disclosure, a method for setting up a safety system for a machine is provided, comprising the following steps:
determining a safety configuration of the safety system for the machine by the method according the first aspect of this disclosure; and
configuring the safety system based on the determined safety configuration.

According to a third aspect of the present disclosure, there is provided a computer program product comprising a computer program comprising program code means for performing a method according to the first aspect of the invention when the computer program is executed on a computer. Further, there may also be provided a computer program product comprising instructions which, when the program is executed by a computer, cause the computer to perform the steps of the method according to the first aspect of the invention.

The method can be implemented using a processing unit or a control device, which may be a general purpose computer or a specialized computer, wherein an appropriate computer program or computer program product is stored and executed, said computer program or computer program product being configured and arranged for determining the safety configuration of the safety system for the machine or for configuring the safety system for the machine according to the aforementioned methods.

The methods are used to safeguard a machine that has at least one hazard location. At least one hazard location means that the machine may have one hazard location or a number of hazard locations. The hazard locations can be mechanical, electrical or thermal hazard locations, for example. At least one hazard location of the machine is predetermined or known in advance. For example, the exact location or region of the hazard location can be determined in advance by a human, for instance by an inspector, or by means of a computer-implemented procedure or program by analyzing the machine or a virtual model of the machine.

Using the disclosed method, the accessibility is determined for a hazard location, in particular for each hazard location of the machine. When determining accessibility, it is determined inter alia whether and how the hazard location is accessible or reachable. Depending on the accessibility, appropriate safety measures can then be taken to safeguard the respective hazard location. For instance, a safety configuration of a safety system for the machine is defined for appropriate protection.

The analysis of accessibility to the hazard location is carried out using a virtual model of the machine in a virtual environment. The virtual environment may comprise a computer-generated, three-dimensional space, which can also be referred to as virtual space. Objects can be modeled, textured and animated using the virtual environment. A virtual environment can be created on a computer using appropriate software programs (such as a graphics engine), for example.

The virtual model of the machine is provided or generated in the virtual environment. The virtual model may be a 3D model of the machine. In particular, the virtual model can be a design model or a CAD (computer-aided design) model. A virtual model of the machine can be based on 3D data of the machine, based on which the virtual model can be generated in the virtual environment and thus made available.

To obtain information about the accessibility of the hazard location, the accessibility of the hazard location of the machine is simulated in the virtual environment based on a number of three-dimensional, geometric shapes. The plurality of geometric shapes thus includes at least two, in particular three or more, geometric shapes. A three-dimensional, geometric shape is a 3D object with a defined shape and size. The plurality of geometric shapes includes at least two different sizes. Preferably, the plurality of geometric shapes can have two or more groups. The geometric shapes in each group have the same size, especially the same shape. However, the groups differ from one another in the shape and size of the geometric forms. In other words, each group has a number of geometric shapes in a different size, especially shape. For example, the plurality of geometric shapes may comprise one or more geometric shapes of a first size (corresponding to a first group), one or more geometric shapes of a second size (corresponding to a second group) and one or more geometric shapes of a third size (corresponding to a third group). Alternatively, each geometric shape of the plurality of geometric shapes can have a different size.

The geometric shapes can be spheres, cylinders or tubes, for example. The size of the geometric shape preferably corresponds to the volume of the geometric shape or the extension of the geometric shape in a certain spatial direction. In the case of a sphere, the size is defined by the radius or diameter. In the case of a cylinder, for example, the size can be defined by the length and/or the radius.

The size of the geometric shapes can be adapted to the dimensions of parts of the human body (e.g. body, arm, hand, finger and fingertip). The plurality of geometric shapes is preferably a plurality of spheres with different sizes (i.e. different diameters). In particular, the diameter of a sphere can be 100 cm to 200 cm (roughly corresponding to an average body size), wherein such a sphere can be referred to as a body sphere.

The diameter of a sphere can also be 4 cm to 12 cm, preferably 5 cm to 10 cm, in particular 7 cm (roughly corresponding to an average arm thickness), wherein such a sphere can be referred to as an arm sphere. The plurality of geometric shapes may include several arm spheres. For example, the plurality of geometric shapes may include three, four, five or more arm spheres. In particular, the number of arm spheres can be selected so that the product of the number and the diameter of the arm spheres is 40 cm to 100 cm, preferably 50 cm to 80 cm, in particular 60 cm or 70 cm (roughly corresponding to an average arm length).

The diameter of a sphere can also be 5 cm to 15 cm, in particular 10 cm (roughly corresponding to the thickness of an average hand), wherein such a sphere can be referred to as a hand sphere. The plurality of geometric shapes may include several hand spheres. For example, the plurality of geometric shapes may include three, four, five or more hand spheres. In particular, the number of hand spheres can be selected so that the product of the number and the diameter of the hand spheres is 5 cm to 20 cm, preferably 7 to 15 cm (roughly corresponding to an average hand length).

The diameter of a sphere can also be 0.5 cm to 2.5 cm, preferably 1 cm to 2 cm, in particular 1.5 cm (roughly corresponding to the thickness of a finger), wherein such a sphere can be referred to as a finger sphere. The plurality of geometric shapes may include several finger spheres. For example, the plurality of geometric shapes may include three, four, five or more finger spheres. In particular, the number of finger spheres can be selected so that the product of the number and the diameter of the finger spheres is 5 cm to 15 cm, preferably 7 cm to 10 cm, in particular 8 cm (roughly corresponding to an average finger length).

Preferably, the plurality of geometric shapes comprises a body sphere, one or more arm spheres and one or more finger spheres. In particular, the plurality of geometric shapes may also include one or more hand spheres. Alternatively, the plurality of geometric shapes may include a body sphere, one or more arm spheres and one or more hand spheres.

To simulate the accessibility of the hazard location, an arrangement of one or more of the geometric shapes around the hazard location is simulated. For this purpose, the arrangement of one geometric shape or a combination of geometric shapes can be considered. For example, it is possible to simulate where one or more of the geometric shapes can be positioned around the hazard location. “Arrangeable” means that a geometric shape is arranged freely in space and does not lie in a component of the machine or overlap with it. The hazard location can be reached with a geometric shape if a geometric shape or a combination of geometric shapes can be arranged in such a way that it is directly adjacent to the hazard location.

The simulation can be limited to a specific region around the hazard location. For simulation purposes, the respective geometric shape can be generated at different positions in the virtual environment, in particular in the specific region around the hazard location. It can then be determined for each position whether the geometric shape can be arranged at this position. Alternatively, the geometric shape can also be generated at only one position in the virtual environment, in particular in the specific region around the hazard location, and then moved around accordingly in the virtual environment.

Based on the simulation of accessibility, the next step is to determine the accessibility of the hazard location. In particular, it is determined whether and how the hazard location is accessible. If, for example, the hazard location cannot be reached with any of the geometric shapes or with any combination of geometric shapes, the hazard location is not accessible. If the hazard location can be reached with a geometric shape or with a specific combination of geometric shapes, the hazard location is accessible with this geometric shape or with this specific combination of geometric shapes.

Based on the determined accessibility of the hazard location, the next step is to determine a corresponding safety configuration of the safety system for the machine.

The safety system can have various safety devices to safeguard hazard locations on the machine. Safety devices can be physical safety devices such as edge protectors, barriers, markings and the like or sensory devices such as sensors, light grids, cameras and the like. A physical safety device can be used to safeguard a hazard location by making access to it more difficult or preventing it by arranging the physical safety device accordingly. A sensory safety device can be used to safeguard a hazard location by monitoring a region, i.e. a safety zone, around the hazard location using the sensory safety device. The region can be defined, for example, by a safety distance from the hazard location. The sensory safety devices can be connected to a control device of the safety system. If it is detected that a person has entered the monitored region or is in the monitored region, appropriate safety measures can be taken. For example, the safety device or the control device of the safety system can be configured to emit an optical or acoustic alarm signal or to switch off the machine if it is detected that a person is entering the monitored region or is in the monitored region.

A safety configuration of the safety system thus defines the arrangement and/or configuration of one or more safety devices of the safety system. The safety configuration can be defined by one or more parameters. A parameter of the safety configuration thus determines the arrangement and/or configuration of one or more safety devices. In other words, a parameter of the safety configuration thus determines a safety measure for safeguarding the hazard location.

If it has been determined that the hazard location is not accessible, no safety measures are required to safeguard the hazard location. In this case, the safety configuration is determined in such a way that no arrangement and/or configuration of one or more safety devices of the safety system is configured to safeguard the hazard location.

If it has been determined that the hazard location is accessible, the required safety measure depends on how the hazard location is accessible, in particular with which geometric shape or which combination of geometric shapes. In particular, the safety configuration can be determined in such a way that the arrangement and/or configuration of one or more safety devices of the safety system are configured to safeguard the hazard location in accordance with the specified accessibility. For example, a fine-mesh finger guard can be fitted directly around the hazard location or a coarse-mesh access guard a little further away.

According to the specific safety configuration of the safety system, the safety system can then be set up accordingly to safeguard the machine's hazard locations when these locations are accessible. A safety measure is implemented to prevent or make it more difficult for a person to injure themselves at the hazard locations. In the various embodiments, the machine is started up and operated with the safety system set up in this way. In particular, the machine can be configured to process and/or pack and/or transport objects after put into operation. For example, in some embodiments, the machine may include a machine tool and/or a robot and/or a conveyor mechanism, such as a conveyor belt, each of which poses a hazard to personnel during operation.

The proposed method thus provides a method for automated determination of accessibility to a hazard location. In particular, the proposed method can be used to automatically determine whether and how a hazard location is accessible. Thus, the proposed method allows CE certification to be carried out automatically. It is also possible to carry out the accessibility analysis using only the design data of the machine, for example the CAD data. Compared to manual CE certification, the proposed method offers the advantage that the determination can be carried out quickly, reliably and, in particular, at an early stage in the development process (for example, on the basis of a CAD design model).

Furthermore, the proposed method determines appropriate protective or safety measures based on the specific accessibility of the hazard locations. For this purpose, the proposed method determines a safety configuration of the safety system based on the specific accessibility to the hazard location. The safety system can then be configured according to the specific safety configuration to safeguard the machine. This improves safety of the machine. In particular, the proposed method improves the detection and safeguarding of hazard locations on a machine.

In a first refinement, in the simulation step, the geometric shapes are used to successively determine a corresponding region in the virtual environment in which the respective geometric shape can be arranged around the hazard location.

By “one after the other” it is meant that first a region for a first geometric shape is determined, then another region for a further geometric shape, and so on. In particular, the regions can be determined in descending or ascending order according to the size of the geometric shapes. The region of the respective geometric shape is a region in the virtual environment that includes in particular all possible arrangements of the geometric shapes around the hazard location. In particular, the determination of where the respective geometric shape can be arranged in the virtual environment around the hazard location can be limited to a specific region of the virtual environment, preferably to the immediate vicinity of the hazard location (for example, within 3 m of the hazard location). In other words, possible (in particular all possible) arrangements (position/orientation) of the geometric shape in the virtual environment (outside the virtual model) and preferably within the limited region are determined for the respective geometric shape, wherein the possible (in particular all possible) arrangements then cover or define the corresponding region of the geometric shape. The region for the respective geometric shape can be made, for example, by scanning (the variation of the position and/or orientation of the geometric shape or motion simulation) the virtual environment (or a limited region of the virtual environment) by means of the respective geometric shape, determining where the geometric shape can be located in the virtual environment or in the limited region of the virtual environment. The region to be determined is then the region that is covered by all specific possible arrangements.

In a further refinement, a subsequent region is determined in such a way that the respective geometric shape can be arranged in this region starting from the previously determined regions around the hazard location.

“Starting from” means that a subsequent geometric shape overlaps with or is directly adjacent to at least one of the previous specific regions. In other words, the corresponding region is first determined for a first geometric shape, where the geometric shape can be arranged in the virtual environment or in the limited region of the virtual environment around the hazard location. Then, for each subsequent geometric shape, it is determined where this geometric shape can be arranged in the virtual environment or in the limited region of the virtual environment starting from at least one of the previously determined regions, wherein these arrangements of the subsequent geometric shape then define the corresponding region. In this way, the arrangement of a combination of geometric shapes can be simulated.

In a further refinement, a first region in the virtual environment around the hazard location is determined in the simulation step, in which a first geometric shape can be arranged around the hazard location, preferably within a defined region.

As previously explained, the first region is determined for the first geometric shape of the plurality of geometric shapes. This determines where the first geometric shape can be arranged in the virtual environment within the defined region. The first region is then the region that is covered by all certain possible arrangements of the first geometric shape. The defined region is preferably a sub-region of the virtual environment. The hazard location is preferably located in the defined region (especially in the middle of the defined region). For example, the first geometric shape can be a sphere. The defined region can, for example, be an enclosure such as a surface, in particular a sphere, which surrounds the virtual model. Alternatively, the first region can also be defined as the region in which the first geometric shape can be arranged directly adjacent to the virtual model of the machine.

In a further refinement, a second region is determined in the virtual environment around the hazard location, in which a second geometric shape can be arranged around the hazard location starting from the first region.

The plurality of geometric shapes includes the second geometric shape. In other words, this determines where the second geometric shape can be arranged in the virtual environment starting from the first region. The second region is then the region that is covered by all certain possible arrangements of the second geometric shape. Preferably, the second geometric shape is smaller than the first geometric shape. For example, the first geometric shape can be a body sphere and the second geometric shape can be an arm sphere.

In a further refinement, a third region is determined in the virtual environment around the hazard location, in which a third geometric shape can be arranged around the hazard location starting from the first and/or the second region.

The plurality of geometric shapes includes the third geometric shape. In other words, this determines where the third geometric shape can be arranged in the virtual environment starting from the first region and/or the second region. The third region is then the region that is covered by all certain possible arrangements of the third geometric shape. Preferably, the third geometric shape is smaller than the first geometric shape and the second geometric shape. For example, the first geometric shape can be a body sphere, the second geometric shape an arm sphere and the third geometric shape a finger sphere. In particular, after determining the third region for other, smaller geometric shapes (for example for a finger sphere and/or a fingertip sphere), further regions can be determined based on at least one of the previously determined regions.

In a further refinement, the regions are determined one after the other in descending order of the size of the geometric shapes.

In particular, the first geometric shape by means of which the first region is determined is then the largest geometric shape of the plurality of geometric shapes. Each additional region is then determined with the next smaller geometric shape. In this way, it is possible to determine in particular whether the hazard location can be reached from the outside to the inside via a combination of geometric shapes arranged in descending order.

In a further refinement, a subsequent region is only determined if none of the previously determined regions are directly adjacent to the hazard location.

As soon as the hazard location is reached with a certain geometric shape, especially if the corresponding region is directly adjacent to the hazard location, it is no longer necessary to consider the subsequent (smaller) geometric shapes. It is therefore advantageous to determine the region of a subsequent geometric shape only if the regions of the previous (larger) geometric shapes are not directly adjacent to the hazard location. In particular, the second region is only determined if the first region is not directly adjacent to the hazard location. Accordingly, the third region is only determined if the first region and the second region are not directly adjacent to the hazard location.

In a further refinement, in the step of determining the accessibility of the hazard location, it is determined that the hazard location is accessible if one of the determined regions is directly adjacent to the hazard location.

Once one of the specified regions is directly adjacent to the hazard location, it indicates that the hazard location has been reached with the corresponding geometric shape of that region. The hazard location is thus accessible. If none of the specified regions are directly adjacent to the hazard location, the hazard location cannot be reached with any of the geometric shapes. The hazard location is thus not accessible. In the step of determining the accessibility, the geometric shape or combination of geometric shapes with which the hazard location is accessible can be determined in particular. If one of the specified regions is directly adjacent to the hazard location, the hazard location is accessible with the corresponding geometric shape (in particular with a combination of the geometric shapes from the first (largest) to the geometric shape whose region is directly adjacent to the hazard location).

In a further, alternative refinement, a first region in the virtual environment around the hazard location is determined in the simulation step, in which a first geometric shape can be arranged directly adjacent to the hazard location.

The plurality of geometric shapes includes a first geometric shape. In particular, the first geometric shape can be one of a plurality of geometric shapes that can be arranged directly adjacent to the hazard location. This first geometric shape is then used to determine a first region around the hazard location in which the first geometric shape can be arranged directly adjacent to the hazard location. Starting from this first region, further regions with larger geometric shapes can then be determined. In this way, it is possible to determine from the inside out whether the hazard location can be reached with a combination of geometric shapes. For example, the first geometric shape can be a finger sphere.

In a further refinement, a second region is determined in the virtual environment around the hazard location, in which the second geometric shape can be arranged around the hazard location starting from the first region.

The plurality of geometric shapes has the second geometric shape. In other words, this determines where the second geometric shape can be arranged in the virtual environment starting from the first region. The second region is then the region that is covered by all certain possible arrangements of the second geometric shape. Preferably, the second geometric shape is larger than the first geometric shape. For example, the first geometric shape can be a finger sphere, and the second geometric shape can be an arm sphere.

In a further refinement, a third region is determined in the virtual environment around the hazard location, in which a third geometric shape can be arranged around the hazard location based on the first and/or second region.

The plurality of geometric shapes has the third geometric shape. In other words, this determines where the third geometric shape can be arranged in the virtual environment starting from the first region and/or the second region. The third region is then the region that is covered by all certain possible arrangements of the third geometric shape. Preferably, the third geometric shape is larger than the first geometric shape and the second geometric shape. For example, the first geometric shape can be a finger sphere, the second geometric shape an arm sphere and the third geometric shape a body sphere.

In a further refinement, the regions are determined one after the other in ascending order of the size of the geometric shapes.

In particular, the first geometric shape based on which the first region is determined is then the largest geometric shape of the plurality of geometric shapes. Each additional region is then determined with the next larger geometric shape. In this way, it is possible to determine in particular whether the hazard location can be reached from the inside to the outside via a combination of geometric shapes arranged in ascending order.

In a further refinement, a subsequent region is only determined if each previous region can be determined.

A region can only be determined if the corresponding geometric shape can be arranged. The first region can be determined if the first geometric shape can be arranged directly adjacent to the hazard location. Each further region, in particular the second and third regions, can be determined if the corresponding geometric shape can be arranged starting from at least one of the already determined regions. For example, the second region is only determined if the first region was determinable. Accordingly, the third region is only determined if the first and second regions could be determined.

If all regions starting with the first region up to the region of the largest geometric shape can be determined, the hazard location can be reached with this combination of geometric shapes. If not all regions can be determined (especially if the region of the largest geometric shape cannot be determined), the hazard location cannot be reached with this combination of geometric shapes. In particular, a new first geometric shape can be determined in this case (the next smaller one to the previous first geometric shape). Then, starting from the new first geometric shape, the regions can be determined one after the other in ascending order of the size of the geometric shapes. If there is no longer a smaller shape, this means that the hazard location is not accessible.

In a further refinement, it is determined in descending order of the size of the geometric shapes one after the other whether the respective geometric shape can be arranged directly adjacent to the hazard location, whereby a geometric shape that can be arranged directly adjacent to the hazard location is determined as the first geometric shape.

In this way, it can be determined whether one geometric shape of the plurality of geometric shapes can be placed directly adjacent to the hazard location and, if so, which is the largest geometric shape that can be placed at the hazard location. If none of the geometric shapes can be arranged directly adjacent to the hazard location, the hazard location cannot be reached with any of the geometric shapes. In particular, in this case no region can be determined that is directly adjacent to the hazard location (i.e. the first region cannot be determined). In this case, the hazard location is not accessible. However, if one of the geometric shapes can be arranged directly adjacent to the hazard location, this geometric shape is determined as the first geometric shape. In particular, the first geometric shape, which can be arranged directly adjacent to the first, is determined to be the first geometric shape.

In a further refinement, in the step of determining the accessibility of the hazard location, it is determined that the hazard location is accessible if all regions to be determined can be determined.

In particular, starting from a first geometric shape, a region is to be determined for each of these shapes in ascending order of the size of the geometric shapes. If a region cannot be determined because none of the geometric shapes can be arranged directly adjacent to the hazard location or because a subsequent (larger) geometric shape cannot be arranged directly adjacent to the previously determined regions, the hazard location is not accessible. In other words, the hazard location is only accessible if all subsequent regions, in particular the region to be determined based on the largest geometric shape, can be determined starting from the first region. Since the first region of the first geometric shape is directly adjacent to the hazard location, the hazard location is accessible with the first geometric shape (in particular with a combination of the geometric shapes from the first to the largest geometric shape).

In a further refinement, the plurality of geometric shapes includes a plurality of spheres.

Spheres have a geometry that can be simulated relatively easily in the virtual environment. Due to their spherical symmetry, the calculation of distances or arrangements of the sphere in the virtual environment can be easier compared to more complex (less symmetrical) objects. In this way, the simulation time can be shortened.

In a further refinement, the safety configuration defines an arrangement and/or configuration of a safety device of the safety system and/or an arrangement of a safety zone around the hazard location and/or a safety distance to the hazard location if the hazard location is accessible.

The safety configuration thus defines one or more measures for safeguarding the hazard location if it has been determined that the hazard location is accessible. The measure is the arrangement and/or configuration of a safety device. An arrangement of a safety device preferably defines the position, orientation, shape and/or size of the safety device. Physical and sensory safety devices as described above may be used as safety devices. A configuration of a safety device defines how the safety device is set up to safeguard the corresponding hazard location. For example, a sensory safety device can be configured to monitor a region defined by a safety distance or a safety zone. A safety zone or safety distance defines a region that a person should not or must not enter or reach. This region is therefore a region to be monitored or safeguarded. Monitoring or safeguarding may be carried out using the corresponding safety devices of the safety system. The safety configuration defined by the parameters is then used to configure the safety system accordingly. In other words, the safety configuration is used to configure the safety devices according to the safety configuration. The arrangement and/or configuration of a safety device and the definition of a safety zone and/or a safety distance thus serve to safeguard the specific mechanical hazard locations. In particular, the safety measures, i.e. the safety configuration, depend on how the hazard location is accessible, i.e. with which geometric shape or which combination of geometric shapes the hazard location can be reached. For example, if the hazard location is accessible with a large sphere (e.g. a body sphere), the hazard location may need to be safeguarded differently than if the hazard location is accessible with a small sphere (e.g. a finger sphere). In this way, the hazard location can be suitably safeguarded if it is accessible.

In a further refinement, a safety device of the safety system is arranged and/or configured based on the safety configuration when configuring the safety system.

The safety device is arranged and configured in such a way that it can safeguard or monitor at least one corresponding hazard location of the machine. For example, a sensory safety device can be configured in such a way that it monitors a region to be monitored around the hazard location. A physical safety device must be configured and arranged in such a way that it safeguards the hazard location, i.e. makes access to the hazard location by a person more difficult or prevents it. In this way, the safeguarding of the machine is implemented accordingly.

In a further refinement, a safety zone or a safety distance can be configured based on the safety configuration when configuring the safety system, wherein the safety zone or the safety distance is monitored or safeguarded by a safety device of the safety system.

For example, a sensory safety device can be provided that is configured to monitor the safety zone or the safety distance. Furthermore, a physical safety device can also be provided, which is configured to safeguard the safety zone or the safety distance. In particular, the safety configuration may also define several safety zones or safety distances for several hazard locations, wherein either one or more sensory safety devices are configured (i.e. arranged and configured accordingly) to monitor the safety zones and/or safety distances to hazard locations. In this way, the safeguarding of the machine is implemented accordingly.

It is understood that the above-mentioned features and those to be explained below can be used not only in the combination indicated in each case, but also in other combinations or on their own, without departing from the scope of the present invention.

### BRIEF DESCRIPTION OF THE DRAWINGS

Embodiments of the invention are shown in the drawings and are explained in more detail in the following description.

FIG. 1 is a schematic view of a machine and a safety system for safeguarding the machine.

FIGS. 2A and 2B show exemplary views of arrangements of a safety device for safeguarding or monitoring a hazard location.

FIG. 3 shows a schematic representation of a first embodiment of a method for determining a safety configuration of a safety system for a machine.

FIG. 4 shows a schematic representation of an embodiment of a method for configuring a safety system for a machine.

FIG. 5 shows a schematic representation of a second embodiment of a method for determining a safety configuration of a safety system for a machine.

FIG. 6 shows a schematic representation of a third embodiment of a method for determining a safety configuration of a safety system for a machine.

FIG. 7 shows a schematic representation of method steps for determining a first geometric shape in the method of FIG. 6.

FIG. 8 shows a schematic representation of method steps for determining the accessibility starting from a first geometric shape in the method shown in FIG. 6.

FIG. 9 shows an exemplary representation of the determination of the accessibility of a first hazard location using the method from FIG. 5.

FIG. 10 shows an exemplary representation of the determination of the accessibility of a first hazard location using the method from FIG. 6.

FIG. 11 shows an exemplary representation of the determination of the accessibility of a second hazard location using the method of FIG. 5.

FIG. 12 shows an exemplary representation of the determination of the accessibility of a second hazard location using the method from FIG. 6.

FIG. 13 shows an exemplary representation of the determination of the accessibility of a third hazard location using the method from FIG. 5.

FIG. 14 shows an exemplary representation of the determination of the accessibility of a third hazard location using the method from FIG. 6.

FIG. 15 shows an exemplary representation of the determination of the accessibility of a fourth hazard location using the method from FIG. 5.

FIG. 16 shows an exemplary representation of the determination of the accessibility of a fourth hazard location using the method from FIG. 6.

### DETAILED DESCRIPTION

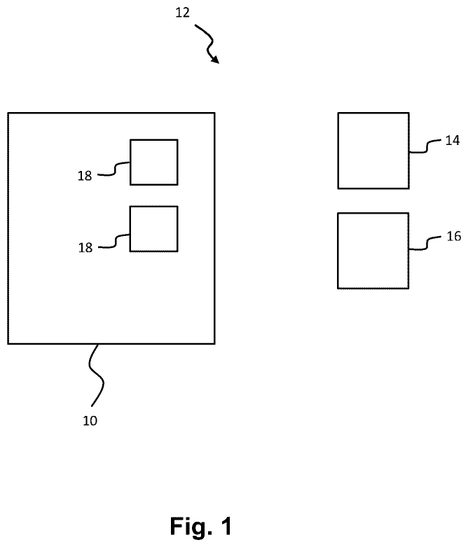

FIG. 1 shows a machine 10 and a safety system 12. The machine 10 has at least one hazard location 18, such as a mechanical, electrical or thermal hazard location. The safety system 12 is used to secure/safeguard the machine 10, in particular to protect the hazard locations 18. The safety system 12 has one or more safety devices 14, 16. The safety devices 14, 16 can be physical safety devices 14 (e.g. barriers, edge protectors, markings, etc.) and/or sensory safety devices 16 (e.g. sensors, cameras, etc.). The hazard locations 18 can be safeguarded by means of the safety devices 14, 16.

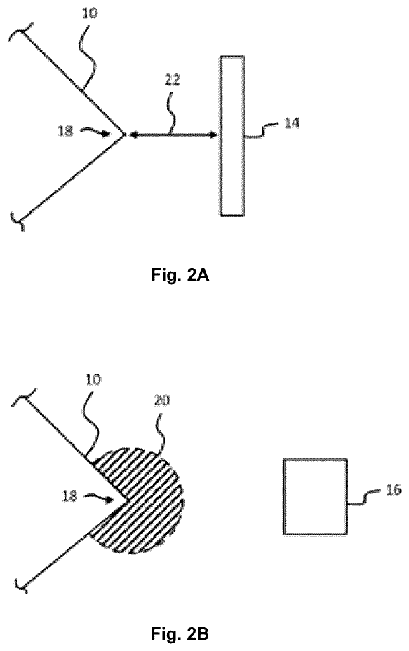

FIG. 2 shows two examples (A) and (B) of safeguarding a mechanical hazard location 18 by means of a safety device 14, 16. These examples of FIG. 2 serve as examples of a safety configuration of the safety system 12. The safety configuration defines an arrangement and/or configuration of safety devices 14, 16 of the safety system 12.

In the first example (A), a physical safety device 14, for example a barrier, is arranged at a certain safety distance 22 from a mechanical hazard location 18 of the machine 10. The physical safety device 14 makes access to the mechanical hazard location 18 more difficult or prevents it.

In the second example (B), a sensory safety device 16, for example a camera or an optical sensor, is arranged in such a way that it monitors a safety zone 20 around a mechanical hazard location 18 of the machine 10. The sensory safety device 16 is configured to detect when a person enters the safety zone 20 and/or is present in the safety zone 20. If the sensory safety device 16 detects this, a safety-related action (alarm, shutdown of the machine, etc.) can be triggered, for example.

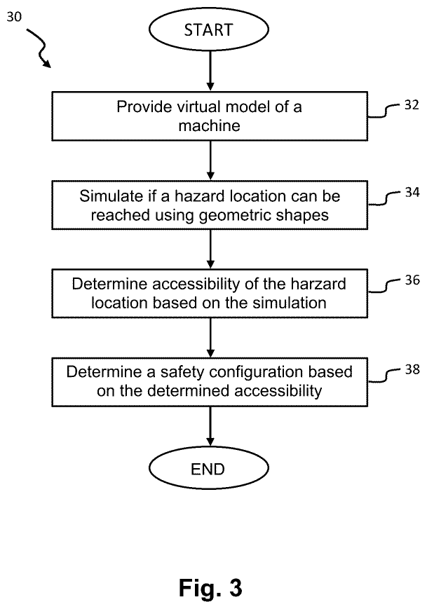

FIG. 3 shows a first embodiment of a method 30 for determining a safety configuration of the safety system 12 for the machine 10, wherein the machine 10 has at least one hazard location 18. The method 30 can be computerized. In particular, the steps of the method 30 may be performed by means of a computer. The method 30 is therefore a computer-implemented method.

In a first step 32 of the method 30, a virtual model of the machine 10 is provided in a virtual environment.

In a further step 34 of the method 30, the accessibility of the hazard location 18 of the machine 10 in the virtual environment is determined based on a plurality of three-dimensional geometric shapes, wherein the plurality of geometric shapes have different sizes.

Preferably, the plurality of geometric shapes includes a plurality of spheres. The sizes of the spheres can be adapted to the dimensions of the human body (body sphere, arm sphere, finger sphere).

In particular, step 34 simulates whether the hazard location can be reached with one geometric shape of the plurality of geometric shapes or with a combination of geometric shapes of the plurality of geometric shapes.

For example, the geometric shapes can be used to successively determine a corresponding region in the virtual environment in which the respective geometric shape can be arranged around the hazard location, wherein a subsequent region is determined in such a way that the respective geometric shape can be arranged around the hazard location in this region based on the previously determined regions.

The accessibility of a hazard location can be determined using a combination of geometric shapes, for example, either towards the hazard location (methodology 1) or away from the hazard location (methodology 2).

According to methodology 1, for example, it is determined whether the hazard location can be reached from the outside via a combination of geometric shapes. For this purpose, a first region is first determined in the virtual environment around the hazard location, in which a first geometric shape can be arranged within a defined region around the hazard location. Here, the first geometric shape is the largest geometric shape. The other regions of the other geometric shapes are then determined one after the other in descending order of the size of the geometric shapes.

For example, a second region is determined in the virtual environment around the hazard location, in which a second geometric shape can be arranged around the hazard location starting from the first region, wherein the second geometric shape is smaller than the first. A third region is then determined in the virtual environment around the hazard location, in which a third geometric shape can be arranged around the hazard location starting from the first and/or second region, wherein the third geometric shape is smaller than the second and first.

According to methodology 2, on the other hand, it is determined whether the combination of geometric shapes can be arranged starting from the hazard location to the outside.

For this purpose, a first region is first determined in the virtual environment around the hazard location, in which a first geometric shape can be arranged directly adjacent to the hazard location. The first geometric shape is therefore one of a plurality of geometric shapes that can be arranged at the hazard location. The other regions are then determined one after the other in ascending order of the size of the geometric shapes.

For example, a second region is determined in the virtual environment around the hazard location, in which the second geometric shape can be arranged starting from the first region around the hazard location, wherein the second geometric shape is larger than the first. A third region is then determined in the virtual environment around the hazard location, in which a third geometric shape can be arranged around the hazard location starting from the first and/or second region, wherein the third geometric shape is larger than the second and first.

In a further step 36 of the method 30, the accessibility of the hazard location 18 is determined based on the simulation of the accessibility of the hazard location 18.

If the hazard location can be reached with a geometric shape or with a combination of connected geometric shapes of the plurality of geometric shapes, the hazard location is accessible. If the hazard location cannot be reached with a geometric shape or with a combination of connected geometric shapes of the plurality of geometric shapes, the hazard location is not accessible.

According to methodology 1, it is determined that the hazard location is accessible if one of the specified regions is directly adjacent to the hazard location. According to methodology 1, if no region can be determined that is directly adjacent to the hazard location, the hazard location is not accessible.

According to methodology 2, it is determined that the hazard location is accessible if all regions to be determined can be determined. If not all regions to be determined can be determined, the hazard location is not accessible.

In a further step 38 of the method 30, the safety configuration is then determined based on the determined accessibility of the hazard location 18. The safety configuration defines an arrangement and/or configuration of a safety device 14, 16 of the safety system 12 and/or an arrangement of a safety zone 20 around the hazard location 18 and/or a safety distance 22 from the hazard location 18 if the hazard location 18 is accessible.

In particular, the safety measures can depend on how the hazard location 18 is accessible, i.e. with which geometric shape or which combination of geometric shapes. For example, if the hazard location is accessible with a large sphere (e.g. a body sphere), the hazard location may need to be safeguarded differently than if the hazard location is accessible with a small sphere (e.g. a finger sphere). In this way, the hazard location can be suitably safeguarded if it is accessible. For example, the number of sensors, the size of the safety region to be monitored or the size of a barrier can be determined based on the size of the geometric shape with which the hazard location 18 is accessible.

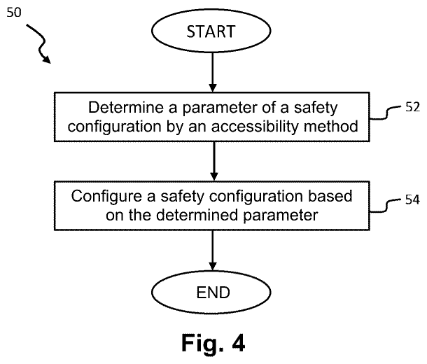

FIG. 4 shows an embodiment of a method 50 for configuring the safety system 12 for the machine 10.

In a first step 52 of the method 50, a safety configuration of the safety system 12 for the machine 10 is determined. The safety configuration of the safety system 12 for the machine 10 can be determined using the method 30 according to FIG. 3.

In a further step 54 of the method 50, the safety system 12 is configured based on the safety configuration defined by the at least one particular parameter. When configuring the safety system 12, a safety device 14, 16 of the safety system 12 may be arranged and/or configured based on the safety configuration. Furthermore, when configuring the safety system 12, a safety zone 20 or a safety distance 22 may be set up based on the safety configuration, wherein the safety zone 20 or the safety distance 22 is monitored or safeguarded by means of a safety device 14, 16 of the safety system 12.

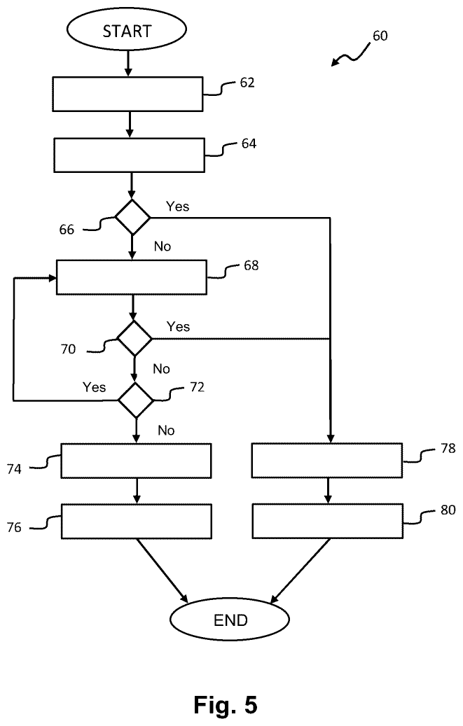

FIG. 5 shows a second embodiment of a method 60 for determining a safety configuration of the safety system 12 for the machine 10, wherein the machine 10 has at least one hazard location 18. The method 60 can be computerized. In particular, the steps of the method 60 may be performed by means of a computer. Method 60 is therefore a computer-implemented method.

In a first step 62 of the method, a virtual model of the machine 10 is provided in a virtual environment. Afterwards, step 64 is carried out.

In step 64 of the method 60, a first region is determined in which a first geometric shape of the plurality of three-dimensional geometric shapes may be disposed in a defined region around the hazard location 18. The first geometric shape is the largest geometric shape of the plurality of three-dimensional geometric shapes.

In step 66 of the method 60, it is determined whether the first region is directly adjacent to the hazard location 18. If the first region is directly adjacent to the hazard location 18, the next step 78 is carried out. If the first region is not adjacent to the hazard location 18, step 68 is carried out.

In step 68 of the method 60, a further region is determined for a next smaller geometric shape of the plurality of three-dimensional geometric shapes, in which the next smaller geometric shape can be arranged starting from at least one of the previously determined regions (in particular starting from the last determined region). The next smallest geometric shape is the largest geometric shape that has not yet been used to determine a region.

In step 70 of the method 60, it is determined whether the region determined in step 68 is directly adjacent to the hazard location 18. If the region determined in step 68 is directly adjacent to the hazard location 18, step 78 is performed next. If the region determined in step 68 is not directly adjacent to the hazard location 18, step 72 is performed.

In step 72 of the method 60, it is determined whether there is still a next smaller geometric shape in the plurality of three-dimensional geometric shapes. If there is a next smaller geometric shape, step 68 is repeated with this next smaller geometric shape. If there is no next smaller geometric shape, step 74 is carried out.

In step 74 of the method 60, it is determined that the hazard location is not accessible because none of the determined regions are directly adjacent to the hazard location. Afterwards, step 76 is carried out.

In step 76 of the method 60, the safety configuration of the safety system is determined such that it does not include any safety measures for safeguarding the hazard location 18.

In a further step 78 of the method 60, it is determined that the hazard location 18 is accessible because one of the determined regions is directly adjacent to the hazard location 18. Preferably, it is determined that the hazard location 18 is accessible by means of the geometric shape of this region. In particular, it can be determined that the hazard location 18 is accessible with a combination of geometric shapes starting from the largest to the one whose region is directly adjacent to the hazard location 18. Afterwards, step 80 is carried out.

In a further step 80 of the method 60, the safety configuration of the safety system is determined such that it includes safety measures for safeguarding the hazard location 18. In particular, the safety measures may depend on how the hazard location is accessible, i.e. with which geometric shape or combination of geometric shapes.

The method 60 essentially corresponds to the method 30 and implements the methodology 1 for determining the reachability and accessibility of the hazard location 18. In particular, step 62 corresponds to step 32. Further, steps 64 to 72 are an example of step 34 using methodology 1. Further, steps 74 and 78 are an example of step 36 using methodology 1. Further, steps 76 and 80 are an example of step 38.

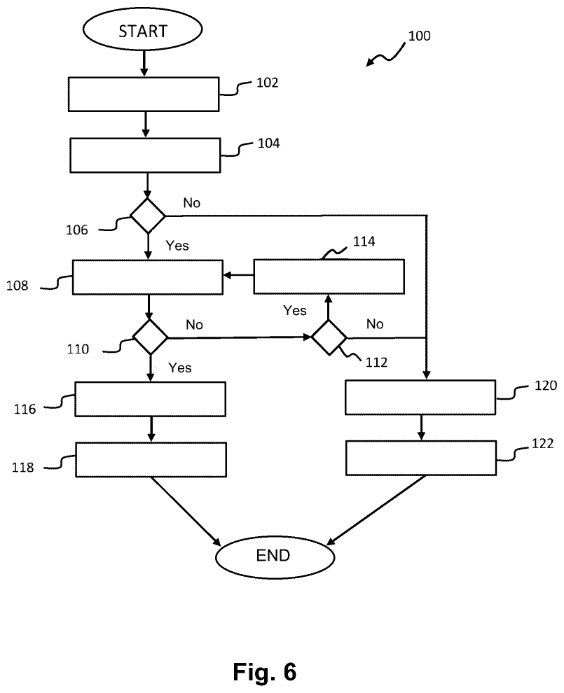

FIG. 6 shows a third embodiment of a method 100 for determining a safety configuration of the safety system 12 for the machine 10, wherein the machine 10 has at least one hazard location 18. The method 100 can be computerized. In particular, the steps of the method 100 may be performed by means of a computer.

In a first step 102 of the method 100, a virtual model of the machine 10 is provided in a virtual environment.

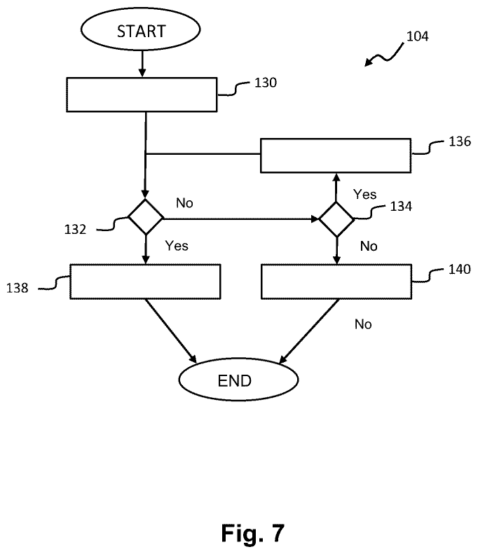

In a further step 104 of the method 100, a first geometric shape of a plurality of three-dimensional geometric shapes that can be arranged directly adjacent to the hazard location 18 is determined. FIG. 7 shows method steps 130 to 140 for determining the first geometric shape in step 104.

In step 130, the largest geometric shape of the plurality of geometric shapes is selected as the geometric shape.

In step 132, it is determined whether the selected geometric shape can be arranged directly adjacent to the hazard location 18. If the selected geometric shape can be arranged directly adjacent to the hazard location 18, step 138 is performed. If the selected geometric shape cannot be arranged directly adjacent to the hazard location 18, step 134 is performed.

In step 134, it is determined whether there is a next smaller geometric shape to the selected geometric shape in the plurality of geometric shapes. If there is a next smaller geometric shape to the selected geometric shape, step 136 is carried out. If there is a next smaller geometric shape to the selected geometric shape, step 140 is carried out.

In step 136, the next smaller geometric shape is determined as the new selected geometric shape. Step 132 is then carried out again with the new geometric shape selected.

In step 138, the selected geometric shape that can be arranged directly adjacent to the hazard location 18 is determined as the first geometric shape.

In step 140, no geometric shape is determined as the first geometric shape because none of the plurality of geometric shapes can be arranged at the hazard location 18.

In a further step 106 of the method 100, it is determined whether a first geometric shape could be determined in the step 104 (see steps 138 and 140). Once an initial geometric shape has been determined, step 108 is carried out. If no first geometric shape could be determined, step 120 is carried out.

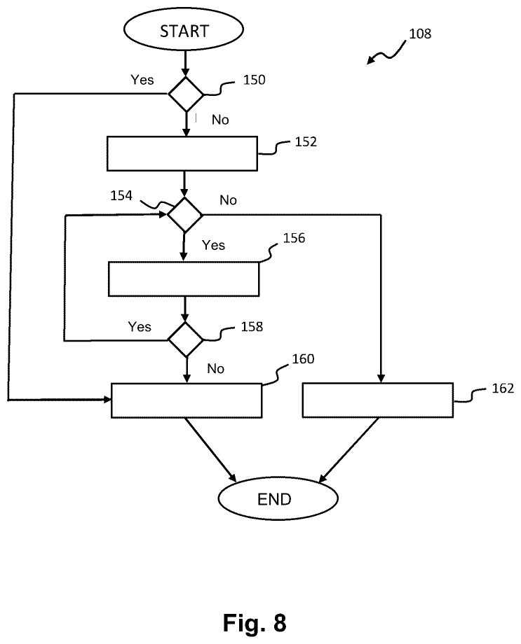

In a further step 108 of the method 100, the accessibility of the hazard location 18 is determined based on the first geometric shape. FIG. 8 shows method steps 150 to 162 for determining the accessibility in the step 108 of the method 100 of FIG. 6.

In step 150, it is determined whether the first geometric shape is the largest geometric shape of the plurality of geometric shapes. If the first geometric shape is the largest geometric shape of the plurality of geometric shapes, step 160 is performed. If the first geometric shape is the largest geometric shape of the plurality of geometric shapes, step 152 is performed.

In step 152, a first region is determined in which the first geometric shape can be arranged directly adjacent to the hazard location 18. Afterwards, step 154 is carried out.

In step 154, it is determined whether a next larger geometric shape of the plurality of three-dimensional geometric shapes can be arranged starting from at least one of the previously determined regions (in particular starting from the last determined region). If the next larger geometric shape can be arranged, step 156 is carried out. If the next larger geometric shape can be arranged, step 162 is carried out.

In step 156, a corresponding region is determined for this next larger geometric shape, in which this next larger geometric shape can be arranged starting from at least one of the previously determined regions (in particular starting from the last determined region). Afterwards, step 158 is carried out.

In step 158, it is determined whether there is a next larger geometric shape in the plurality of geometric shapes (in particular for which no range has yet been determined). If there is a next larger geometric shape, step 154 is carried out again. If there is no next larger geometric shape, step 160 is carried out.

In step 160, it is determined that the hazard location can be reached starting from the first geometric shape because all regions (to be determined) can be determined.

In step 160, it is determined that the hazard location can be reached starting from the first geometric shape because all regions (to be determined) can be determined.

In a further step 110 of the method 100, it is determined whether all regions could be determined in step 162 (i.e. whether the hazard location can be reached starting from the first geometric shape). When all regions have been determined, step 116 is carried out. If not all regions could be determined, step 112 is carried out.

In a further step 112 of the method 100, it is determined whether there is a next smaller geometric shape to the first geometric shape in the plurality of geometric shapes. If there is a next smaller geometric shape, step 114 is carried out. If there is no next smaller geometric shape, step 120 is carried out.

In a further step 114 of the method 100, the next smaller geometric shape is determined as the new first geometric shape. Step 108 is then carried out again with the new first geometric shape. Before step 108 is carried out again, it is preferable to first determine whether the new first geometric shape can be arranged directly adjacent to the hazard location.

In a further step 116 of the method 100, it is determined that the hazard location 18 is accessible because all regions starting from the first geometric shape could be determined. Preferably, it is determined that the hazard location 18 is accessible by means of the first geometric shape. In particular, it can be determined that the hazard location 18 is accessible with a combination of geometric shapes starting from the largest to the first geometric shape. Afterwards, step 118 is carried out.

In a further step 118 of the method 100, the safety configuration of the safety system is determined such that it includes safety measures for safeguarding the hazard location 18. In particular, the safety measures may depend on how the hazard location is accessible, i.e. with which geometric shape or combination of geometric shapes.

In a further step 120 of the method 100, it is determined that the hazard location is not accessible. Afterwards, step 122 is carried out.

In a further step 122 of the method 100, the safety configuration of the safety system is determined such that it does not include any safety measures for safeguarding the hazard location 18.

The method 100 essentially corresponds to method 30 and implements methodology 2 for determining the reachability and accessibility of the hazard location 18. In particular, step 102 corresponds to step 32. Further, steps 104 to 114 are an example of step 34 using methodology 2. Further, steps 116 and 120 are an example of step 36 using methodology 2. Further, steps 118 and 122 are an example of step 38.

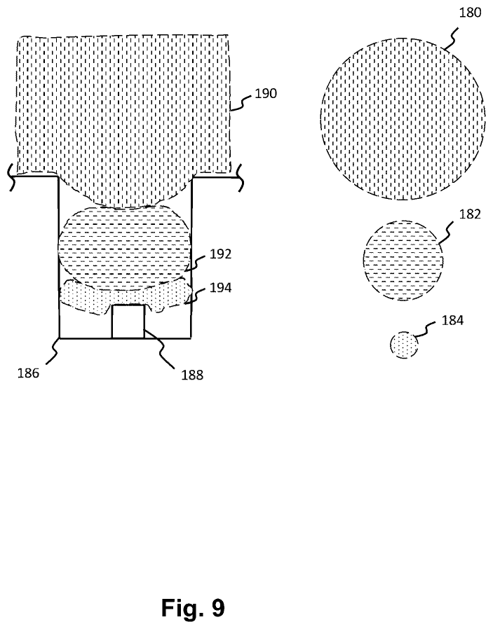

FIGS. 9 to 12 describe the methodologies 1 and 2 using the example of a first (accessible) hazard location 188 and a second (non-accessible) hazard location 210 of a machine 186. To simulate reachability, three spheres 180, 182, 184 with different diameters are used in both methodologies as the plurality of three-dimensional geometric shapes. The sphere 180 has the largest diameter. Sphere 184 has the smallest diameter. The sphere 180 can be a body sphere. The sphere 182 can be an arm sphere. sphere 184 can be a finger sphere.

FIG. 9 shows an example of how methodology 1 (in particular method 60 of FIG. 5) can be used to determine whether the first hazard location 188 is accessible.

First, a first region 190 is determined in which the sphere 180 can be arranged in a defined region around the first hazard location 188. A second region 192 is then determined, in which the sphere 182 can be arranged starting from the first region 190. A third region 194 is then determined, in which the sphere 184 can be arranged starting from the first region 190 and/or the second region 192.

In the example shown in FIG. 9, the third region 194 is directly adjacent to the first hazard location 188. The first hazard location 188 can therefore be reached via a combination of spheres 180, 182, 184. The first hazard location 188 is therefore accessible.

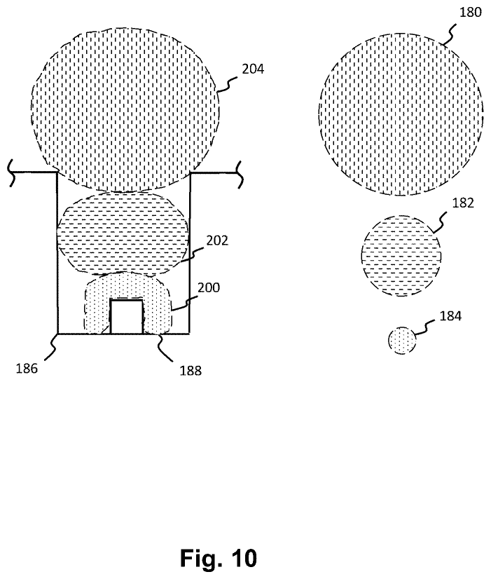

FIG. 10 shows an example of how methodology 2 (in particular the method 100 of FIG. 6) can be used to determine whether the first hazard location 188 is accessible.

First, a first region 200 is determined in which the sphere 184 can be arranged directly adjacent to the first hazard location 188. A second region 202 is then determined, in which the sphere 182 can be arranged starting from the first region 200. A third region 204 is then determined, in which the sphere 180 can be arranged starting from the first region 200 and/or the second region 202.

In the example of FIG. 10, each of the three regions 200, 202, 204 can be determined. The first hazard location 188 can therefore be reached via a combination of spheres 180, 182, 184. The first hazard location 188 is therefore accessible.

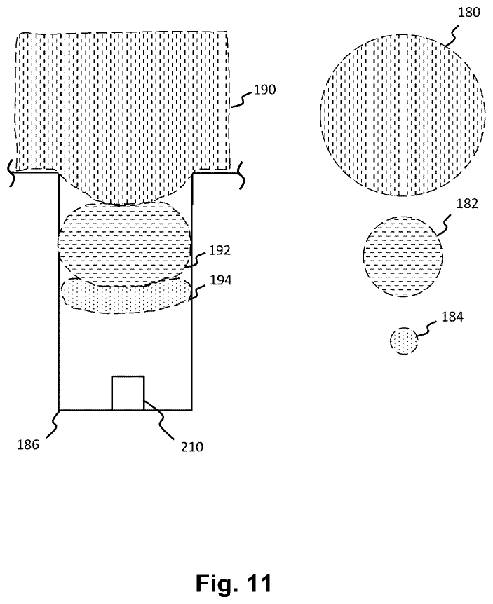

FIG. 11 shows an example of how methodology 1 (in particular method 60 of FIG. 5) can be used to determine whether the second hazard location 210 is accessible.

First, a first region 190 is determined in which the sphere 180 can be arranged in a defined region around the first hazard location 188. A second region 192 is then determined, in which the sphere 182 can be arranged starting from the first region 190. A third region 194 is then determined, in which the sphere 184 can be arranged starting from the first region 190 and/or the second region 192.

In the example shown in FIG. 11, the third region 194 is not directly adjacent to the second hazard location 210. The second hazard location 210 is therefore not accessible via a combination of the spheres 180, 182, 184. The second hazard location 210 is therefore not accessible.

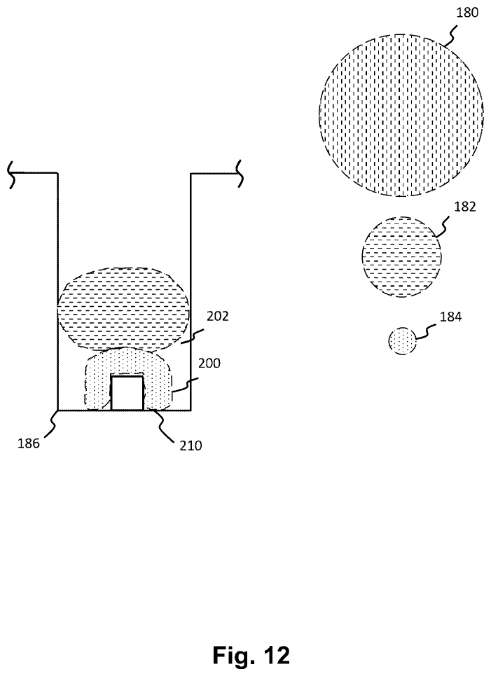

FIG. 12 shows an example of how methodology 2 (in particular method 100 of FIG. 6) can be used to determine whether the second hazard location 210 is accessible.

First, a first region 200 is determined in which the sphere 184 can be arranged directly adjacent to the second hazard location 210. A second region 202 is then determined, in which the sphere 182 can be arranged starting from the first region 200. However, the third region 204 cannot be determined for the sphere 180 because the sphere all 180 cannot be arranged starting from the first region 200 or the second region 202.

In the example of FIG. 12, each of the three regions 200, 202, 204 cannot be determined because the third region 204 cannot be determined. The second hazard location 210 is therefore not accessible via a combination of the spheres 180, 182, 184. The second hazard location 210 is therefore not accessible.

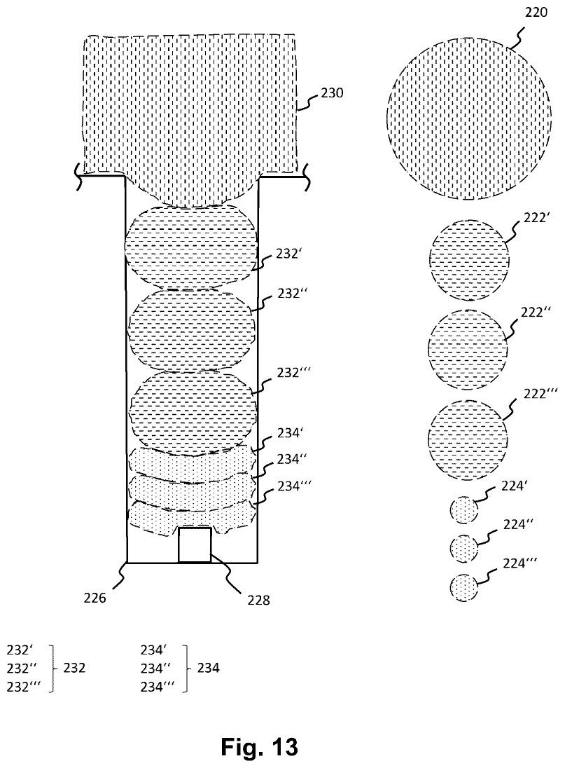

FIG. 13 to 16 describe the methodologies 1 and 2 using the example of a third (accessible) hazard location 228 and a fourth (non-accessible) hazard location 250 of a machine 226. To simulate reachability, both methodologies use seven spheres 220, 222′, 222″, 222′″, 224′, 224′″, 224′″ with different diameters as the plurality of three-dimensional geometric shapes. The spheres 222′, 222″, 222′″ have the same diameter. The spheres 224′, 224″, 224′″ have the same diameter. The sphere 220 has the largest diameter. The spheres 224′, 224″, 224′″ have the smallest diameter. The sphere 220 can represent a body sphere, for example. The spheres 222′, 222″, 222′″ can represent arm spheres, for example. The spheres 224′, 224″, 224′″ can represent finger spheres, for example.

FIG. 13 shows an example of how methodology 1 (in particular the method 60 of FIG. 5) can be used to determine whether the third hazard location 228 is accessible.

First, a first region 230 is determined in which the sphere 220 can be arranged in a defined region around the third hazard location 228. A region 232′ is then determined in which the sphere 222′ can be arranged starting from the region 230. A region 232″ is then determined in which the sphere 222″ can be arranged starting from the region 232′. A region 232′″ is then determined in which the sphere 222′″ can be arranged starting from the region 232″. A region 234′ is then determined in which the sphere 224′ can be arranged starting from the region 232′″. A region 234″ is then determined in which the sphere 224″ can be arranged starting from the region 234′. A region 234′″ is then determined in which the sphere 224′″ can be arranged starting from the region 234″.

In the example of FIG. 13, the last region 234′″ is directly adjacent to the third hazard location 228. The third hazard location 228 can therefore be reached via a combination of spheres 220, 222′, 222″, 222′″, 224′, 224′″, 224′″. The third hazard location 228 is therefore accessible.

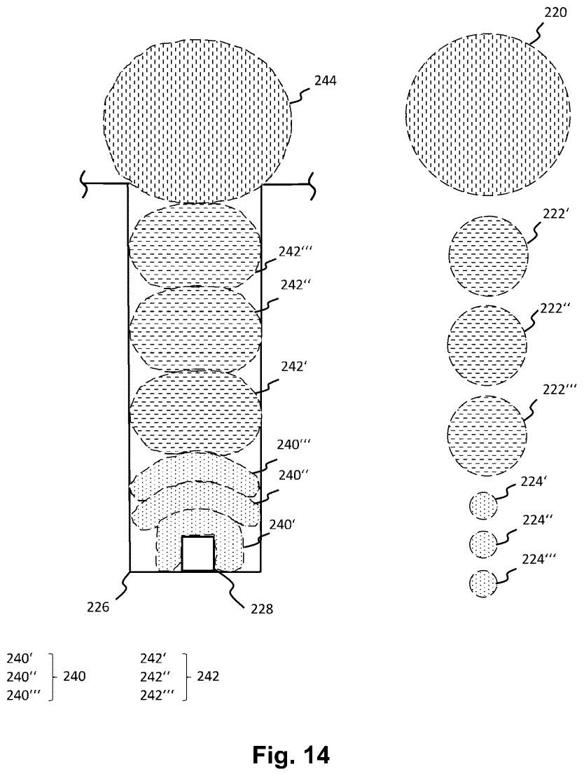

FIG. 14 shows an example of how methodology 2 (in particular method 100 of FIG. 6) can be used to determine whether the third hazard location 228 is accessible.

First, a first region 240′ is determined in which the sphere 224′″ can be arranged directly adjacent to the third hazard location 228. A region 240″ is then determined in which the sphere 224″ can be arranged starting from the region 240′. A region 240′″ is then determined in which the sphere 224′ can be arranged starting from the region 240″. A region 242′ is then determined in which the sphere 222′″ can be arranged starting from the region 240′″. A region 242″ is then determined in which the sphere 222″ can be arranged starting from the region 242′. A region 242′″ is then determined in which the sphere 222′ can be arranged starting from the region 242″. A region 244 is then determined in which the sphere 220 can be arranged starting from the region 242′″.

In the example of FIG. 14, each of the three regions 240′, 240″, 240′″, 242′, 242″, 242′″, 244 can be determined. The third hazard location 228 can therefore be reached via a combination of spheres 220, 222′, 222″, 222′″, 224′, 224′″, 224′″. The third hazard location 228 is therefore accessible.

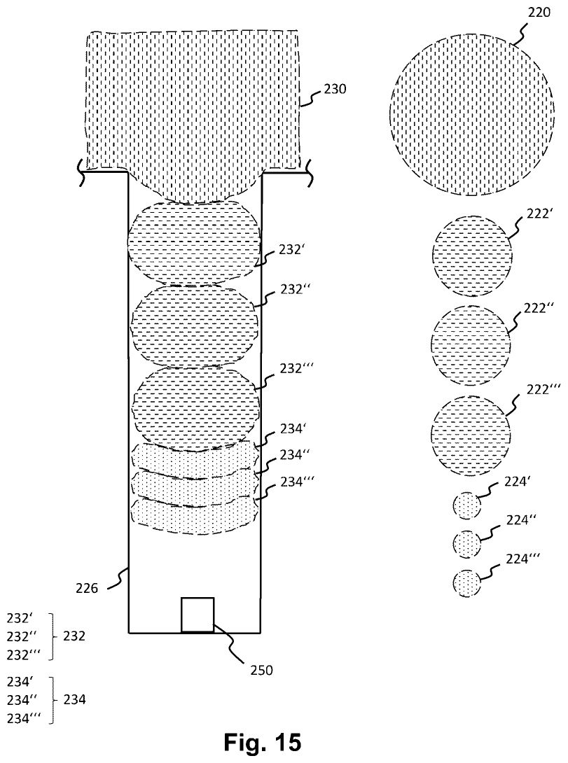

FIG. 15 shows an example of how methodology 1 (in particular method 60 of FIG. 5) can be used to determine whether the fourth hazard location 250 is accessible.

First, a first region 230 is determined in which the sphere 220 can be arranged in a defined region around the fourth hazard location 250. A region 232′ is then determined in which the sphere 222′ can be arranged starting from the region 230. A region 232″ is then determined in which the sphere 222″ can be arranged starting from the region 232′. A region 232′″ is then determined in which the sphere 222′″ can be arranged starting from the region 232″. A region 234′ is then determined in which the sphere 224′ can be arranged starting from the region 232′″. A region 234″ is then determined in which the sphere 224″ can be arranged starting from the region 234′. A region 234′″ is then determined in which the sphere 224′″ can be arranged starting from the region 234″.

In the example of FIG. 15, the last region 234′″ is not directly adjacent to the fourth hazard location 250. The fourth hazard location 250 is therefore not accessible via a combination of spheres 220, 222′, 222′″, 222′″, 224″, 224′″, 224′″. The fourth hazard location 250 is therefore not accessible.

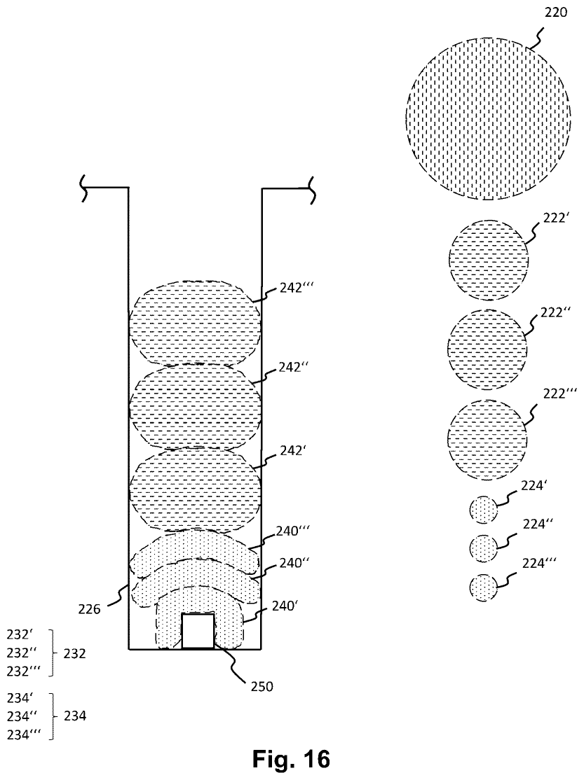

FIG. 16 shows an example of how methodology 2 (in particular method 100 of FIG. 6) can be used to determine whether the fourth hazard location 250 is accessible.

First, a first region 240′ is determined in which the sphere 224′″ can be arranged directly adjacent to the fourth hazard location 250. A region 240″ is then determined in which the sphere 224″ can be arranged starting from the region 240′. A region 240′″ is then determined in which the sphere 224′ can be arranged starting from the region 240″. A region 242′ is then determined in which the sphere 222′″ can be arranged starting from the region 240′″. A region 242″ is then determined in which the sphere 222″ can be arranged starting from the region 242′. A region 242′″ is then determined in which the sphere 222′ can be arranged starting from the region 242″. However, the region 244 cannot be determined for the sphere 220 (in contrast to the example in FIG. 14) because the sphere 220 cannot be arranged starting from the region 242′″.

In the example of FIG. 16, each of the three regions 240′, 240″, 240′″, 242′, 242″, 242′″, 244 cannot be determined because the last region 244 cannot be determined for the sphere 220. The fourth hazard location 250 is therefore not accessible via a combination of spheres 220, 222′, 222′″, 222′″, 224″, 224′″, 224′″. The fourth hazard location 250 is therefore not accessible.

The phrase at least one of A, B, and C should be construed to mean a logical (A OR B OR C), using a non-exclusive logical OR, and should not be construed to mean “at least one of A, at least one of B, and at least one of C.”

What is claimed is:

1. A computer-implemented method for determining a safety configuration of a safety system for a machine having a hazard location, the method comprising:
providing a virtual model of the machine in a virtual environment;
simulating an accessibility of the hazard location of the machine in the virtual environment based on a plurality of three-dimensional geometric shapes, wherein the plurality of geometric shapes has at least two different sizes;
determining the accessibility of the hazard location based on the simulation of the accessibility of the hazard location; and
determining the safety configuration based on the accessibility of the hazard location.

2. The method of claim 1 wherein, the simulating is based on the geometric shapes, successively a region in the virtual environment is determined in which the respective geometric shape can be arranged around the hazard location.

3. The method of claim 2 wherein a subsequent region is determined in such a way that the respective geometric shape can be arranged in this region starting from previously determined regions around the hazard location.

4. The method of claim 1 wherein, during the simulating, a first region in the virtual environment around the hazard location is determined, in which a first geometric shape can be arranged within a defined region around the hazard location.

5. The method of claim 4 wherein:
a second region is determined in the virtual environment around the hazard location, in which a second geometric shape can be arranged starting from the first region around the hazard location, and
a third region is determined in the virtual environment around the hazard location, in which a third geometric shape can be arranged starting from at least one of the first and the second region around the hazard location.

6. The method of claim 2 wherein the regions are determined one after another in descending order of the size of the geometric shapes.

7. The method of claim 3 wherein a subsequent region is determined only in response to none of the previously determined regions being directly adjacent to the hazard location.

8. The method of claim 2 wherein, during the determining the accessibility of the hazard location, the hazard location is determined to be accessible in response to one of the determined regions being directly adjacent to the hazard location.

9. The method of claim 1 wherein, during the simulating, a first region in the virtual environment around the hazard location is determined, in which a first geometric shape can be arranged directly adjacent to the hazard location.

10. The method of claim 9 wherein:
a second region is determined in the virtual environment around the hazard location, in which a second geometric shape can be arranged starting from the first region around the hazard location, and
a third region is determined in the virtual environment around the hazard location, in which a third geometric shape can be arranged starting from the at least one of the first and second region around the hazard location.

11. The method of claim 2 wherein the regions are determined in ascending order of the size of the geometric shapes one after another.

12. The method of claim 2 wherein a subsequent region is determined only in response to each previous region being determinable.

13. The method of claim 9 wherein:
it is successively determined in descending order of the size of the geometric shapes whether the respective geometric shape can be arranged directly adjacent to the hazard location, and
a geometric shape which can be arranged directly adjacent to the hazard location is determined as the first geometric shape.

14. The method of claim 2 wherein, during the determining the accessibility of the hazard location, the hazard location is determined to be accessible in response to all regions to be determined being determinable.

15. The method of claim 1 wherein the plurality of geometric shapes is a plurality of spheres.

16. The method of claim 1 wherein the safety configuration defines at least one of an arrangement of a safety device of the safety system, a configuration of a safety device of the safety system, an arrangement of a safety zone around the hazard location, and a safety distance to the hazard location when the hazard location is accessible.

17. A method of setting up a safety system for a machine, the method comprising:
determining a safety configuration of the safety system for the machine by the method of claim 1; and
configuring the safety system based on the determined safety configuration.

18. The method of claim 17 wherein, when configuring the safety system, a safety device of the safety system is at least one of arranged and configured based on the determined safety configuration.

19. The method of claim 17 wherein, when configuring the safety system, a safety zone or a safety distance is configured based on the determined safety configuration, wherein the safety zone or the safety distance is monitored or safeguarded by a safety device of the safety system.

20. A computer program product comprising a computer program having program code means for performing the method of claim 1 when the computer program is executed on a computer.
